(19) United States
(12) Patent Application Publication
(10) Pub. No.: US 2010/0012367 A1
(43) Pub. Date: Jan. 21, 2010

(54) PRINTED CIRCUIT BOARD ARRANGEMENT

(75) Inventors: Marc Andre De Samber, Eindhoven (NL); Koen Van Os, Eindhoven (NL)

Correspondence Address: PHILIPS INTELLECTUAL PROPERTY & STANDARDS, PO BOX 3001, BRIARCLIFF MANOR, NY, 10510-8001, US

(73) Assignee: KONINKLIJKE PHILIPS ELECTRONICS N.V., EINDHOVEN (NL)

(21) Appl. No.: 11/722,342

(22) PCT Filed: Dec. 14, 2005
(86) PCT No.: PCT/IB05/54244

§ 371 Date: Jun. 20, 2007

(30) Foreign Application Priority Data
Dec. 21, 2004 (US) 04106756.2

(51) Int. Cl. H05K 1/11

(52) U.S. Cl. 174/266

(57) ABSTRACT

The present invention relates to a printed circuit board arrangement with a multi-layer substrate (1, 2) having a buried conductor (4) and a contact area (3), connected to the conductor (4) and being disposed on a surface of the substrate. In order to improve the cooling of the buried conductor, a metal cooling area (6) is provided above the conductor (4), and is connected to the conductor by means of one or more via conductors (7).

### FIELD OF THE INVENTION

The present invention relates to a printed circuit board arrangement, comprising a multi-layer substrate, a plated contact area on a surface of the substrate, and a planar conductor, buried beneath the surface of the multi-layer substrate and being connected to the plated contact area.

### BACKGROUND OF THE INVENTION

Such a printed circuit board arrangement is illustrated e.g. in U.S. Pat. No. 6,593,535. The use of a buried planar conductor may provide a free area around the plated contact area. This free area can be used attach other elements in the vicinity of the plated contact area. For instance, if a light emitting diode LED is connected, by soldering, to the plated contact area, the free area may be used to attach an optical element, such as a collimator or a lens for cooperation with the LED.

A drawback with such an arrangement is the considerable thermal resistance experienced by the buried conductor. In the case where a LED is connected to the contact area, the buried conductor will (particularly in a LED lighting arrangement) receive a considerable heat flow, dissipated form the LED. Since the buried conductor must dissipate this heat through a substrate sub-layer, its average temperature will be high. This also means that less heat will be dissipated from the LED, such that the operating temperature of the LED will also be high, which results in a short LED life.

### SUMMARY OF THE INVENTION

It is therefore an object of the present invention to provide a printed circuit board arrangement of the above-mentioned kind where the buried conductor may be kept at a lower operating temperature.

This object is achieved with a printed circuit board arrangement as claimed in claim 1. The printed circuit board arrangement then comprises a multi-layer substrate, a plated contact area on a surface of the substrate, and a planar conductor, buried beneath the surface of the multi-layer substrate and being connected to the plated contact area. The arrangement further comprises a plated metal cooling area, disposed on a surface of the substrate, over the conductor and at a distance from the contact area. The plated metal cooling area is connected to the conductor by means of at least one via conductor, penetrating a sub-layer of the substrate. This arrangement provides enhanced cooling of the buried conductor and hence also of a component attached to the contact area.

The plated metal cooling area may be elongated and connected to the planar conductor by means of a plurality of spaced-apart via conductors. This provides even further enhanced cooling of the buried planar conductor.

The via conductors may comprise plated through-holes.

A cooling flange may be attached to the plated metal cooling area.

The buried conductor may extend in two directions from the point where it is connected to the plated contact area. The conductor may thus comprise two separate branches. Then each branch may comprise a metal cooling area, at a distance from the contact area, which may be connected to the respective branches each by means of at least one via conductor. This further increases the heat dissipation from a component soldered to the contact area.

These and other aspects of the invention will be apparent from and elucidated with reference to the embodiments described hereinafter.

### BRIEF DESCRIPTION OF THE DRAWINGS

FIG. 1 is an exploded perspective view of a printed circuit board arrangement according to an embodiment of the invention.

FIG. 2 illustrates a cross section through the printed circuit board arrangement of FIG. 1, along the line A-A.

FIG. 3 is a front view of a printed circuit board arrangement layout according to an embodiment of the invention.

### DESCRIPTION OF PREFERRED EMBODIMENTS

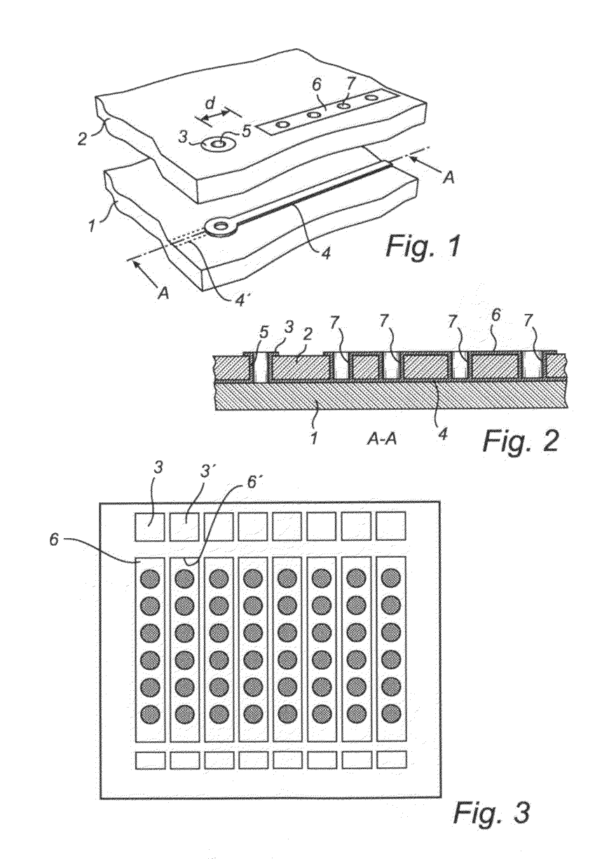

FIG. 1 is an exploded perspective view of a printed circuit board arrangement according to an embodiment of the invention. FIG. 2 illustrates a cross section through the printed circuit board arrangement of FIG. 1, along the line A-A. The arrangement comprises a multi-layer substrate, comprising at least two laminated sub-layers 1, 2. These sub-layers may consist of glass fiber reinforced epoxy, and the substrate may thus be e.g. a so-called FR-4-substrate. As illustrated, one outer sub-layer surface comprises a plated contact area 3.

A metal conductor pattern may be etched on one of the sub-layers 1, 2 before lamination, such that a buried conductor pattern may exist beneath the main surfaces of the finished substrate. The multi-layer substrate thus comprises a planar conductor 4, buried beneath a surface of the multi-layer substrate. The conductor thus extends in a plane between the main surfaces of the finished substrate. This planar conductor 4, which may consist of copper, is connected to the plated contact area 3 by means of a via conductor, such as a plated through hole 5. The planar conductor 4 may be used to feed a current to an electronic component (not shown) such as a light emitting diode (LED), a connection terminal of which is soldered to the plated contact area 3.

The use of a buried planar conductor 4 provides a free area around the plated contact area 3, which may be used e.g. for the mounting of an optical component such as a collimator or a lens.

The buried arrangement of the planar conductor 4 however makes the dissipation of heat from the planar conductor 4 less efficient, since each substrate sub-layer between the conductor and the ambient air provides a thermal resistance. In order to improve the heat dissipation from the planar conductor 4, the arrangement comprises a metal cooling area 6, which is disposed on an outer surface of the multi-layer substrate. The cooling area is disposed over the planar conductor 4 and at a distance d (e.g. in the range from 3-10 mm) from the contact area 3 in order to obtain a free area around the contact area 2. That the cooling area 6 is disposed over the conductor 4 means that the metal cooling area 6 overlaps the metal conductor 4 as seen from the normal of the plane of the substrate, although they are separated by at least one substrate sub-layer 2.

The plated metal cooling area 6 is connected to the buried planar conductor 4 by means of at least one via conductor 7, penetrating a sub-layer of the substrate, namely the sub-layer/layers between the buried conductor and the cooling area 6. The metal cooling area 6 may as illustrated be elongated and connected to the planar conductor by means of a plurality of spaced-apart via conductors 7.

These via conductors 7 may comprise plated through-holes, which per se are well known in the art. It is also possible to fill these through-holes with a metal medium in order to further increase the heat transfer from the buried conductor to the metal cooling area.

The metal cooling area 6 may e.g. have the dimensions 3×30 mm. It may consist of a Cu pattern that is formed on the substrate by plating and etching, but it is also possible to solder the cooling area 6 as a metal sheet onto the via conductors 7. The cooling area may preferably be relatively thick, e.g. 0.5 mm. As illustrated, it may be placed on the same main surface of the substrate as the contact area 3, but it is also possible to place it on the opposite main surface.

A cooling flange (not shown) may be attached to the plated metal cooling area 6 to further increase its heat dissipating capacity.

The metal cooling area 6 (including any cooling flange) may be electrically floating, except for the connection to the conductor 4, i.e. it may be connected to the conductor only. The cooling area may thus be electrically inactive, except for the provision of stray capacitances and the like. The conductor 4 may extend in two directions from the point where it is connected to the plated contact area 3. The conductor may thus as indicated in FIG. 1 comprise a second branch 4′ in addition to the first branch 4. Each branch may comprise its own a metal cooling area 6 (only the cooling area of the first branch 4 is shown in FIG. 1), at a distance from the contact area 3, and may be connected to this by means of each at least one via conductor. Although the angle 180° between the branches is indicated in FIG. 1, other angles are conceivable.

FIG. 3 is a front view of a printed circuit board arrangement layout according to an embodiment of the invention. A number of buried conductors (not visible) are then connected to their individual contact areas 3, 3′, etc. Each conductor further has its own connected cooling area 6, 6′, etc. It is possible to solder an individual cooling flange on top of each cooling area. However, if an insulating glue with low thermal resistance can be used, a common cooling flange may be attached, which covers some or all-cooling areas.

In summary, the invention relates to a printed circuit board arrangement with a multi-layer substrate having a buried conductor and a contact area, connected to the buried conductor and being disposed on a surface of the substrate. In order to improve the cooling of the buried conductor, a metal cooling area is provided above the conductor, and is connected to the conductor by means of one or more via conductors.

The invention is not restricted to the described embodiments. It can be altered in different ways within the scope of the appended claims.

1. Printed circuit board arrangement, comprising a multi-layer substrate, a plated contact area on a surface of the substrate, and a planar conductor, buried beneath the surface of the multi-layer substrate and being connected to the plated contact area, wherein the arrangement comprises a metal cooling area, disposed on a surface of the substrate, over the conductor and at a distance from the contact area, and wherein the metal cooling area is connected to the conductor by means of at least one via conductor, penetrating a sub-layer of the substrate.

2. Printed circuit board arrangement according to claim 1, wherein the metal cooling area is elongated and connected to the planar conductor by means of a plurality of spaced-apart via conductors.

3. Printed circuit board arrangement according to claim 1, wherein the at least one via conductor comprises a plated through-hole.

4. Printed circuit board arrangement according to claim 1, wherein a cooling flange is attached to the plated metal cooling area.

5. Printed circuit board arrangement according to claim 1, wherein the conductor extends in two directions from the point where it is connected to the plated contact area, thus comprising two branches, and wherein each branch comprises a metal cooling area, at a distance from the contact area, which are connected to the respective branches, each by means of at least one via conductor.
